(19) United States
(12) Patent Application Publication
(10) Pub. No.: US 2025/0241178 A1
(43) Pub. Date: Jul. 24, 2025

(54) DISPLAY DEVICE AND METHOD OF MANUFACTURING DISPLAY DEVICE

(71) Applicant: Samsung Display Co., LTD., Yongin-si (KR)

(72) Inventors: Sun Kyu JOO, Yongin-si (KR); Jae Cheol PARK, Yongin-si (KR); Keun Chan OH, Yongin-si (KR); You Young JIN, Yongin-si (KR); Tae Hyung HWANG, Yongin-si (KR)

(73) Assignee: Samsung Display Co., LTD., Yongin-si (KR)

(21) Appl. No.: 18/913,604

(22) Filed: Oct. 11, 2024

(30) Foreign Application Priority Data
Jan. 24, 2024 (KR) 10-2024-0011140

(51) Int. Cl. H10K 59/80; H10K 59/12; H10K 59/122; H10K 59/38; H10K 102/00

(52) U.S. Cl. CPC H10K 59/877; H10K 59/1201; H10K 59/122; H10K 59/38; H10K 59/878; H10K 2102/331

(57) ABSTRACT

A display device and a method of manufacturing a display device. The display device may include a display layer, and a light controlling layer disposed on the display layer, the light controlling layer may include a first bank, a metal layer on at least a portion disposed on the first bank and exposing a top surface of the first bank, and a second bank on at least a portion disposed on the metal layer and exposing the top surface of the first bank.

### CROSS-REFERENCE TO RELATED APPLICATIONS

This application claims priority under 35 U.S.C. § 119 from Korean Patent Application No. 10-2024-0011140 filed on Jan. 24, 2024 in the Korean Intellectual Property Office, the entire contents of which are incorporated herein by reference.

### BACKGROUND

### 1. Technical Field

The disclosure generally relates to a display device and a method of manufacturing a display device.

### 2. Description of the Related Art

Recently, as interest in information displays increases, research and development of display devices is being continuously conducted.

### SUMMARY

Embodiments provide a display device and a method of manufacturing a display device in which light emission efficiency can be improved.

Embodiments also provide a display device and a method of manufacturing a display device in which process efficiency can be improved.

Embodiments also provide a display device and a method of manufacturing a display device in which damage of layers forming the display device can be prevented.

According to an aspect of the disclosure, there is provided a display device that may include a display layer; and a light controlling layer disposed on the display layer, the light controlling layer may include a first bank, a metal layer which may have at least a portion disposed on the first bank and may expose a top surface of the first bank, and a second bank which may have at least a portion disposed on the metal layer and may expose the top surface of the first bank.

The light controlling layer may include a light controlling structure of which at least a portion may be disposed in an area surrounded by the first bank. The light controlling structure may include a color conversion layer including a quantum dot and a light scattering layer including a scatterer.

The display device may further include a first sub-pixel area to which light of a first color may be provided, a second sub-pixel area to which light of a second color may be provided, and a third sub-pixel area to which light of a third color may be provided. The color conversion layer may include a first color conversion layer disposed in the first sub-pixel area and a second color conversion layer disposed in the second sub-pixel area. The light scattering layer may be disposed in the third sub-pixel area.

The display device may further include a color filter layer including a first color filter overlapping the first sub-pixel area, a second color filter overlapping the second sub-pixel area, and a third color filter overlapping the third sub-pixel area. The display layer may include a light emitting element providing light including a light component of the third color.

Each of the first bank and the second bank may include a light transmissive material. The metal layer may include a reflective material.

The metal layer may be entirely covered by the second bank in a plan view.

A side surface of the metal layer may be exposed by the second bank.

The metal layer may include a structure retracted with respect to the second bank.

The display device may further include a spacer disposed on the top surface of the first bank. The spacer and the second bank may include a same material.

The display device may further include a lower capping layer passivating the second bank and the light controlling structure. The lower capping layer may be in contact with a portion of the top surface of the first bank that may be exposed by the metal layer.

The first bank and the second bank may be physically spaced apart from each other.

The display device may further include a first sub-pixel area to which light of a first color may be provided, a second sub-pixel area to which light of a second color may be provided, and a third sub-pixel area to which light of a third color may be provided. In a plan view, the first bank may not overlap the first sub-pixel area and the second sub-pixel area, and the first bank may overlap the third sub-pixel area.

The first color may be red, the second color may be green, and the third color may be blue.

The first bank may include a scatterer.

According to another aspect of the disclosure, there may be provided a method of manufacturing a display device, the method may include manufacturing a display layer; and forming a light controlling layer on the display layer, wherein the forming of the light controlling layer may include patterning a first bank; forming a base metal layer covering the first bank; patterning a second bank and a spacer which cover the base metal layer; removing at least a portion of the base metal layer which may be exposed by the second bank; and forming a light controlling structure in an area surrounded by the first bank.

The metal layer including a reflective surface may be formed by the removing of the at least the portion of the base metal layer. Each of the first bank and the second bank may include a light transmissive material. The metal layer may include a reflective material.

The method may further include forming a lower capping layer passivating the second bank and the light controlling structure. In the forming of the lower capping layer, the metal layer may be entirely covered by the second bank in a plan view.

The display device may include a first sub-pixel area to which light of a first color may be provided, a second sub-pixel area to which light of a second color may be provided, and a third sub-pixel area to which light of a third color may be provided. The forming of the light controlling structure may include forming a first color conversion layer including a first quantum dot in the first sub-pixel area; forming a second color conversion layer including a second quantum dot in the second sub-pixel area; and forming a light scattering layer including a scatterer in the third sub-pixel area.

The method may further include forming a lower capping layer passivating the second bank and the light controlling structure. The display device may include a first sub-pixel area to which light of a first color may be provided, a second sub-pixel area to which light of a second color may be provided, and a third sub-pixel area to which light of a third color may be provided. The first bank may include a scatterer, and the first bank may overlap the third sub-pixel area in a plan view.

The lower capping layer and the first bank may be in contact with each other in the third sub-pixel area.

### BRIEF DESCRIPTION OF THE DRAWINGS

An additional appreciation according to the embodiments of the disclosure will become more apparent by describing in detail the embodiments thereof with reference to the accompanying drawings, wherein:

FIG. 1 is a schematic plan view illustrating a display device according to an embodiment of the disclosure;

FIG. 2 is a schematic plan view illustrating a pixel according to an embodiment of the disclosure;

FIG. 3 is a schematic sectional view illustrating a display device according to an embodiment of the disclosure;

FIG. 4 is a schematic sectional view illustrating a display layer according to an embodiment of the disclosure;

FIGS. 5 and 6 are schematic cutaway sectional views taken along line A-A′ shown in FIG. 2;

FIG. 7 is a flowchart illustrating a method of manufacturing a display device according to an embodiment of the disclosure;

FIG. 8 is a flowchart illustrating detailed steps of a step of forming a light controlling layer on a display layer according to an embodiment of the disclosure; and

FIGS. 9 to 23 are schematic sectional views illustrating process steps of the method of manufacturing the display device according to an embodiment of the disclosure.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals and/or reference characters denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may be different directions that are not perpendicular to one another.

For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, parts, and/or modules. Those skilled in the art will appreciate that these blocks, parts, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, parts, and/or modules being implemented by microprocessors or other similar hardware, they may be programmed and controlled using software (e.g., microcode) to perform various functions discussed herein and may optionally be driven by firmware and/or software. It is also contemplated that each block, part, and/or module may be implemented by dedicated hardware, or as a combination of dedicated hardware to perform some functions and a processor (e.g., one or more programmed microprocessors and associated circuitry) to perform other functions. Also, each block, part, and/or module of some embodiments may be physically separated into two or more interacting and discrete blocks, parts, and/or modules without departing from the scope of the inventive concepts. Further, the blocks, parts, and/or modules of some embodiments may be physically combined into more complex blocks, parts, and/or modules without departing from the scope of the inventive concepts.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

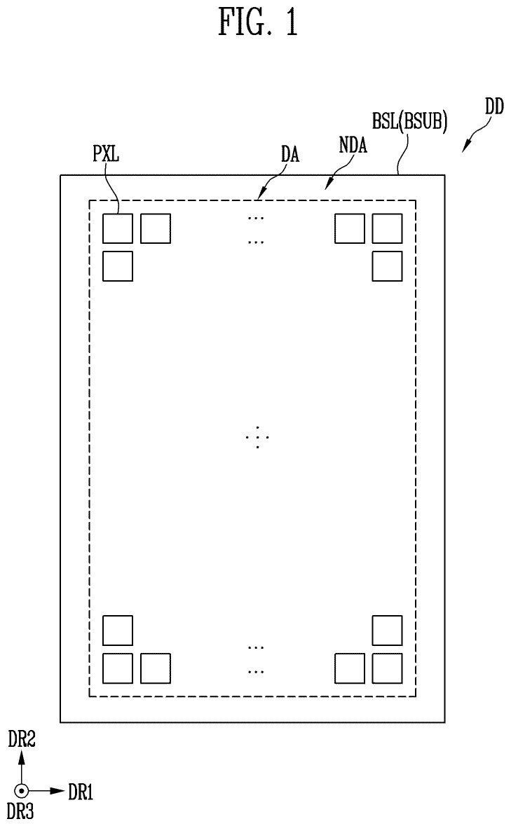

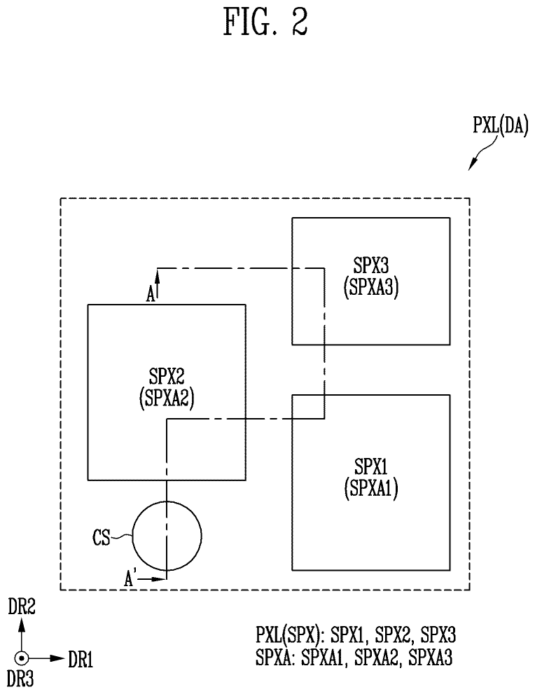

FIG. 1 is a schematic plan view illustrating a display device according to an embodiment of the disclosure. FIG. 2 is a schematic plan view illustrating a pixel according to an embodiment of the disclosure.

Referring to FIGS. 1 and 2, the display device DD may include a base layer BSL and pixels PXL disposed on the base layer BSL. Although not shown in the drawing, the display device DD may further include a driving circuit (e.g., a scan driver and a data driver) for driving the pixels PXL, lines, and pads.

The display device DD (or the base layer BSL) may include a display area DA and a non-display area NDA. The non-display area NDA may mean an area except (or external to) the display area DA. The non-display area NDA may surround at least a portion of the display area DA.

The base layer BSL may form a base surface of the display device DD. The base layer BSL may be a rigid or flexible substrate or film. For example, the base layer BSL may include a glass material. In another example, the base layer BSL may include a silicon material. In another example, the base layer BSL may include polyimide. However, the disclosure is not limited thereto.

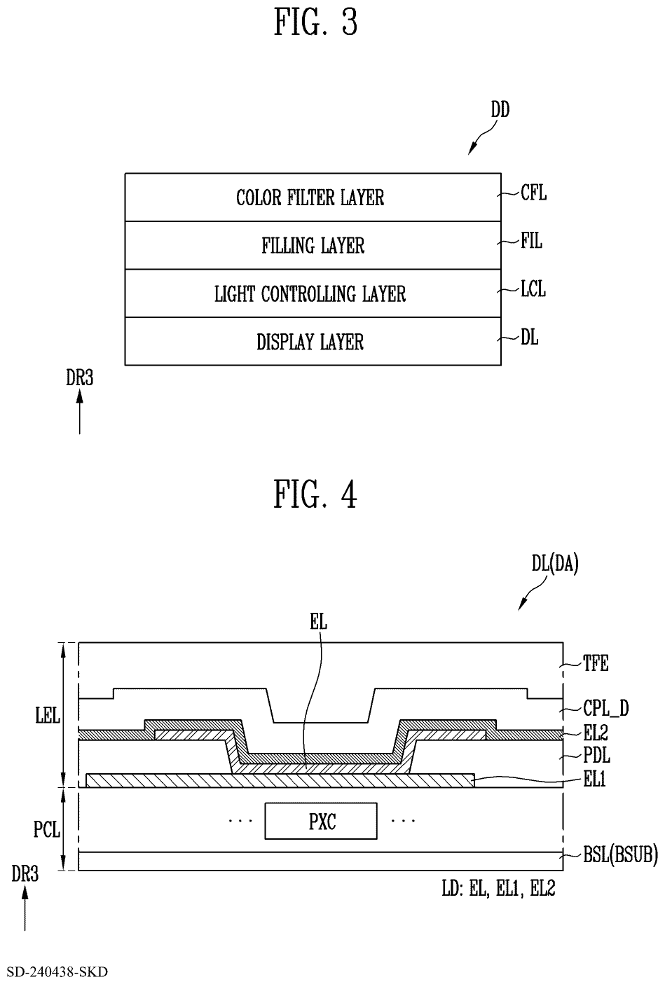

In some embodiments, the base layer BSL may be a lower substrate BSUB. For example, the base layer BSL may be, as the lower substrate BSUB, a base substrate for forming a display layer (see FIG. 3) and a light controlling layer LCL (see FIG. 3).

The display area DA may mean an area in which the pixels PXL are disposed. The non-display area NDA may mean an area in which the pixels PXL are not disposed. The driving circuit, the lines, and the pads, which may be electrically connected to the pixels PXL of the display area DA, may be disposed in the non-display area NDA.

According to an embodiment, the pixels PXL (or sub-pixels SPX) may be arranged according to a stripe arrangement structure, a PENTILE™ arrangement structure, or the like. However, the disclosure is not limited thereto, and various embodiments may be applied in the disclosure.

According to an embodiment, a pixel PXL (or sub-pixels SPX) may include a first sub-pixel SPX1, a second sub-pixel SPX2, and a third sub-pixel SPX3. Each of the first sub-pixel SPX1, the second sub-pixel SPX2, and the third sub-pixel SPX3 may be a sub-pixel. At least one first sub-pixel SPX1, at least one second sub-pixel SPX2, and at least one third sub-pixel SPX3 may form a pixel part capable of emitting light of various colors.

Each of the first sub-pixel SPX1, the second sub-pixel SPX2, and the third sub-pixel SPX3 may emit light of a color. For example, the sub-pixel SPX may form a sub-pixel area SPXA in which light of a color may be emitted. The sub-pixel area SPXA may include a first sub-pixel area SPXA1 in which the first sub-pixel SPX1 formed to provide light of a first color, a second sub-pixel area SPXA2 in which the second sub-pixel SPX2 is formed to provide light of a second color, and a third sub-pixel area SPXA3 in which the third sub-pixel SPX3 is formed to provide light of a third color.

In some embodiments, the first sub-pixel SPX1 may be a red pixel emitting light of red (e.g., the first color), the second sub-pixel SPX2 may be a green pixel emitting light of green (e.g., the second color), and the third sub-pixel SPX3 may be a blue pixel emitting light of blue (e.g., the third color). The red pixel may provide light in a wavelength band of about 600 nm to about 750 nm. The green pixel may provide light in a wavelength band of about 480 nm to about 560 nm. The blue pixel may provide light in a wavelength band of about 370 nm to about 460 nm.

According to an embodiment, a number of second sub-pixels SPX2 may be greater than a number of first sub-pixels SPX1 and a number of third sub-pixels SPX3. However, the color, kind, and/or number of first, second, and third sub-pixels SPX1, SPX2, and SPX3 constituting each pixel part are not limited to a specific example.

In some embodiments, the display device DD (e.g., the pixel PXL) may further include a spacer CS. The spacer CS may not overlap the sub-pixel areas SPXA in a plan view. The spacer CS may be adjacent to the sub-pixel area SPXA, and the position of the spacer CS is not limited to a specific example.

The plane defined in this specification may be a plane extending in a first direction DR1 and a second direction DR2, and may be defined with respect to a plane on which the base layer BSL may be disposed. In some embodiments, a third direction DR3 may be a thickness direction of the base layer BSL. The third direction DR3 may be a light emission direction of the display device DD.

FIG. 3 is a schematic sectional view illustrating a display device according to an embodiment of the disclosure. FIG. 4 is a schematic sectional view illustrating a display layer according to an embodiment of the disclosure.

Referring to FIGS. 3 and 4, the display device DD may include a display layer DL, a light controlling layer LCL, a filling layer FIL, and a color filter layer CFL.

The display layer DL may be configured to emit light. The display layer DL may form a base on which the light controlling layer LCL may be disposed.

The display layer DL may include a pixel circuit layer PCL including a base layer BSL and a light emitting element layer LEL including a light emitting element LD, thereby forming a pixel PXL.

The base layer BSL may form a base on which a pixel circuit PXC may be disposed. The pixel circuit PXC may be disposed on the base layer BSL and be configured to drive the light emitting element LD. The pixel circuit layer PCL may include conductive layers and insulating layers, and the conductive layers may form the pixel circuit PXC. The pixel circuit PXC may include circuit elements capable of driving a sub-pixel SPX (or the light emitting element LD). The circuit elements may include a driving transistor, and include an additional transistor and capacitors.

The light emitting element layer LEL may be disposed on the pixel circuit layer PCL. In some embodiments, the light emitting elements LEL may include the light emitting element LD.

For example (see FIG. 4), the light emitting element LD may include an Organic Light Emitting Diode (OLED) including an organic material. FIG. 4 schematically illustrates an embodiment in which the light emitting element LD may be an OLED, and schematically illustrates a sectional structure of the display layer DL including the pixel circuit layer PCL and the light emitting element layer LEL as a sectional structure of the display device DD in a display area DA.

In some embodiments, the light emitting element layer LEL may further include a pixel defining layer PDL, an element upper capping layer CPL_D, and an encapsulation layer TFE.

In some embodiments, the light emitting element LD may be disposed on the pixel circuit layer PCL. The light emitting element LD may include a first light emitting element included in a first sub-pixel SPX1 (see FIG. 2), a second light emitting element included in a second sub-pixel SPX2 (see FIG. 2), and a third light emitting element included in a third sub-pixel SPX3 (see FIG. 2).

In some embodiments, the light emitting element LD may include a first electrode EL1, a light emitting part EL, and a second electrode EL2. In some embodiments, the light emitting part EL may be disposed in an area defined by the pixel defining layer PDL. A surface of the light emitting part EL may be electrically connected to the first electrode EL1, and the other surface of the light emitting part EL may be electrically connected to the second electrode EL2.

The first electrode EL1 may be an anode electrode of the light emitting part EL, and the second electrode EL2 may be a cathode electrode of the light emitting part EL. In some embodiments, the first electrode EL1 and the second electrode EL2 may include a conductive material. For example, the conductive material may include at least one selected from the group consisting of gold (Au), silver (Ag), aluminum (Al), molybdenum (Mo), chromium (Cr), titanium (Ti), nickel (Ni), neodymium (Nd), copper (Cu), and platinum (Pt). In another example and in some embodiments, the conductive material may include at least one selected from the group consisting of silver nano wire (AgNW), Indium Tin Oxide (ITO), Indium Zinc Oxide (IZO), Indium Gallium Zinc Oxide (IGZO), Antimony Zinc Oxide (AZO), Indium Tin Zinc Oxide (ITZO), Zinc Oxide (ZnO), Tin Oxide (SnO₂), carbon nano tube, and graphene. However, the disclosure is not necessarily limited thereto.

The light emitting part EL may emit light, based on an electrical signal provided from the anode electrode (e.g., the first electrode EL1) and the cathode electrode (e.g., the second electrode EL2).

The light emitting part EL may include a multi-layer structure. For example, the light emitting part EL may include multiple light emitting structures each including a hole transport part, a light emitting layer (or light generation layer), and an electron transport part. Each of the layers forming the light emitting part EL may include an organic material. In some embodiments, each of the layers forming the light emitting part EL may further include a metal-containing compound, an inorganic material such as a quantum dot, the like, or a combination thereof.

The hole transport part may include a multi-layer structure having multiple layers including different materials. In an example, the hole transport part may include at least one of a hole injection layer and a hole transport layer. In some embodiments, the hole transport part may further include a light emitting auxiliary layer, an electron blocking layer, and the like. For example, the hole transport part may have a multi-layer structure of the hole injection layer/the hole transport layer, the hole injection layer/the hole transport layer/the light emitting auxiliary layer, the hole injection layer/the light emitting auxiliary layer, the hole transport layer/the light emitting auxiliary layer, the electron blocking layer/the hole injection layer/the hole transport layer, hole transport layers which may be sequentially disposed and include different materials, the hole injection layer/the hole transport layer/the electron blocking layer, or the like. However, the disclosure is not limited to a specific example.

The light emitting layer of the light emitting part EL may include a material capable of emitting light of a color. In some embodiments, the light emitting part EL may emit light of a third color (e.g., blue). The light emitting layer may include a host and a dopant. The host of the light emitting layer may be a light emitting material capable of capturing carriers (electrons and holes) for generating light, and may induce excitons to be efficiently generated. The dopant of the light emitting layer EL may include a phosphorescent dopant and a fluorescent dopant. In some embodiments, examples of the dopant are not particularly limited. In some embodiments, the dopant may include an organic material. The dopant may also include a metal complex and the like.

The electron transport part may include a multi-layer structure having multiple layers including different materials. The electron transport part may include at least one of an electron injection layer and an electron transport layer. In some embodiments, the electron transport part may further include an electron control layer, an electron buffer layer, a hole blocking layer, and the like. For example, the electron transport part may have a multi-layer structure of the electron transport layer/the electron injection layer, the hole blocking layer/the electron transport layer/the electron injection layer, the electron control layer/the electron transport layer/the electron injection layer, the electron buffer layer/the electron transport layer/the electron injection layer, or the like. However, the disclosure is not limited to a specific example.

The pixel defining layer PDL may be disposed on the pixel circuit layer PCL to define a position at which the light emitting part EL is disposed. The pixel defining layer PDL may include an organic material. For example, the pixel defining layer PDL may include at least one selected from the group consisting of acrylic resin, epoxy resin, phenolic resin, polyamide resin, and polyimide resin. However, the disclosure is not limited thereto. In an embodiment, the pixel defining layer PDL may include an inorganic material. For example, the pixel defining layer PDL may include at least one of silicon oxide (SiOₓ) and silicon nitride (SiNₓ). In some embodiments, the pixel defining layer PDL may have a multi-layer structure in which a layer including silicon oxide (SiOₓ) and a layer including silicon nitride (SiNₓ) may be stacked on each other.

The element upper capping layer CPL_D may be disposed over the second electrode EL2. The element upper capping layer CPL_D may cap the second electrode EL2. The element upper capping layer CPL_D may include an inorganic material.

The encapsulation layer TFE may be disposed over the light emitting element LD (e.g., the second electrode EL2). The encapsulation layer TFE may cancel a step difference generated by the light emitting element LD and the pixel defining layer PDL. The encapsulation layer TFE may include multiple insulating layers covering the light emitting element LD. In some embodiments, the encapsulation layer TFE may have a structure in which an inorganic layer and an organic layer may be alternately stacked on each other. In some embodiments, the encapsulation layer TFE may be a thin film encapsulation layer.

In another example, the light emitting element LD may be an inorganic light emitting diode including an inorganic material. In an example, the display device DD may include a structure in which light emitting elements LD including an inorganic material may be aligned between multiple electrodes spaced apart from each other. In another example, the display device DD may include a structure in which the light emitting element LD may be transferred as a micro LED (light emitting diode) onto the pixel circuit layer PCL based on a transfer method. The transfer method may be one of a transfer method using a stamp, a transfer method using a laser, a transfer method using an electrostatic force, and a transfer method using an adhesive. However, the disclosure is not limited thereto.

The light controlling layer LCL may be disposed on the display layer DL (e.g., the light emitting element layer LEL). For example, the light controlling layer LCL may be disposed at an upper side of the display layer DL with respect to a display direction (e.g., the third direction DR3).

In some embodiments, the light controlling layer LCL may include a layer capable of changing a color of applied light, and include a layer capable of scattering the applied light.

The filling layer FIL may be disposed between the light controlling layer LCL and the color filter layer CFL. In some embodiments, the filling layer FIL may include a filling material, and be disposed between the light controlling layer LCL and the color filter layer CFL during a process of bonding the light controlling layer LCL and the color filter layer CFL to each other.

The color filter layer CFL may be disposed on the light controlling layer LCL. For example, the color filter layer CFL may be disposed at an upper side of the light controlling layer LCL with respect to the display direction (e.g., the third direction DR3).

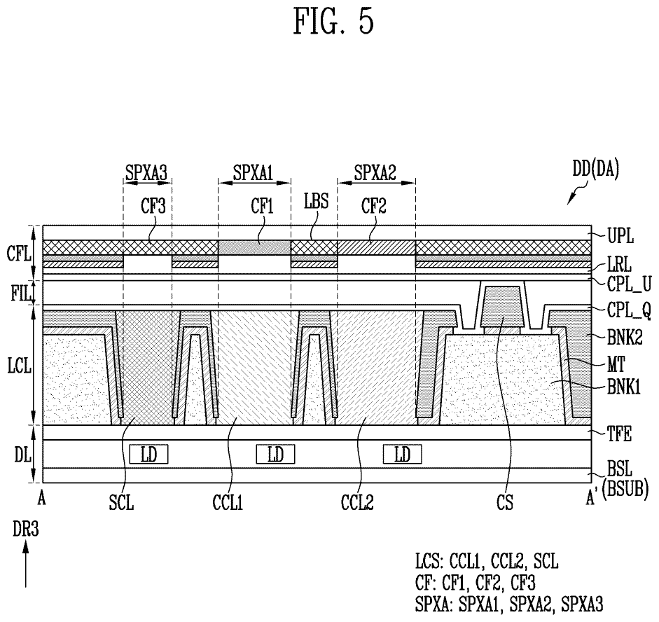

In some embodiments, the color filter layer CFL may include an upper layer UPL (see FIG. 5) and color filters CF (FIG. 5) which may be disposed on the bottom of the upper layer UPL and allow light of a color to be selectively transmitted therethrough. In some embodiments, the upper layer UPL may be an upper substrate for disposing the color filters CF. However, the disclosure is not limited thereto.

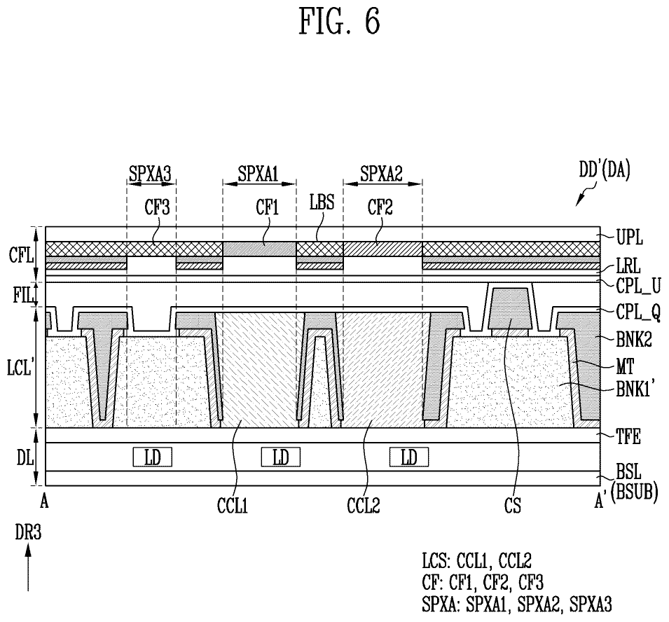

A structural feature in which the display device DD implements a full-color display will be described with reference to FIGS. 5 and 6. In FIGS. 5 and 6, portions overlapping with those described above will be briefly described or will not be repeated.

FIGS. 5 and 6 are schematic cutaway sectional views taken along line A-A′ shown in FIG. 2. FIG. 5 is a schematic sectional view illustrating a display device according to an embodiment of the disclosure. FIG. 6 is a schematic sectional view illustrating a display device according to an embodiment of the disclosure.

First, a display device DD according to an embodiment of the disclosure will be described with reference to FIG. 5.

In some embodiments, a light emitting element LD in a display layer DL may emit light including a light component of a third color. For example, the light emitting element LD may emit light of the third color. The light emitting element LD may emit light including a light component of a second color and the light component of the third color.

A light controlling layer LCL may be disposed on the display layer DL including light emitting elements LD. For example, the light controlling layer LCL may be disposed on an encapsulation layer TFE.

The light controlling layer LCL may include a first bank BNK1, a metal layer MT, a second bank BNK2, light controlling structures LCS, and a lower capping layer CPL_Q.

The first bank BNK1 may be disposed on the display layer DL. The first bank BNK1 may be disposed (e.g., directly disposed) on the encapsulation layer TFE.

The first bank BNK1 may be disposed in a partial area on the display layer DL. The first bank BNK1 may be patterned and may expose a portion of the display layer DL.

The first bank BNK1 may protrude in a thickness direction of a base layer BSL (e.g., the third direction DR3). The first bank BNK1 may surround an area and form spaces in which the light controlling structures LCS can be disposed.

In some embodiments, the first bank BNK1 may not overlap sub-pixel areas SPXA in a plan view. For example, the first bank BNK1 may be disposed between the sub-pixel areas SPXA in a plan view.

The first bank BNK1 may include a side surface facing the light controlling structure LCS. The side surface of the first bank BNK1 may form a base on which the metal layer MT may be disposed.

The first bank BNK1 may be spaced apart from the second bank BNK2. The first bank BNK1 may not be in contact with the second bank BNK2. At least a portion of the first bank BNK1 may not overlap the second bank BNK2 in a plan view. A top surface of the first bank BNK1 may be exposed by the metal layer MT and the second bank BNK2. In some embodiments, at least a portion of the first bank BNK1 may be adjacent (e.g., directly adjacent) to (e.g., in contact with) the lower capping layer CPL_Q.

The first bank BNK1 may include a light transmissive material (e.g., a transparent material). The first bank BNK1 may not include a light blocking material. For example, the first bank BNK1 may include an organic material. In some embodiments, the first bank BNK1 may include an acrylic material. However, the disclosure is not limited thereto.

In some embodiments, as the first bank BNK1 adjacent to the light controlling structure LCS may include the light transmissive material instead of the light blocking material, a light loss risk of light provided by the light emitting element LD can be reduced, and accordingly light emission efficiency can be improved.

The metal layer MT may be disposed over the first bank BNK1. The metal layer MT may cover the side surface of the first bank BNK1. A portion of the metal layer MT may be disposed on the encapsulation layer TFE. Accordingly, the metal layer MT may face the light controlling structure LCS and form a light recycling structure. Thus, the light emission efficiency of the display device DD can be improved.

The metal layer MT may include a reflective material (e.g., a reflective metal material). For example, the metal layer may include at least one selected from the group consisting of gold (Au), silver (Ag), aluminum (Al), molybdenum (Mo), chromium (Cr), titanium (Ti), nickel (Ni), neodymium (Nd), copper (Cu), and platinum (Pt). However, the disclosure is not limited thereto.

The metal layer MT may expose the top surface of the first bank BNK1. The metal layer MT may be partially disposed on the top surface of the first bank BNK1. The metal layer MT may be covered by the second bank BNK2. The metal layer MT may overlap the second bank BNK2 in a plan view. The metal layer MT may be entirely covered by the second bank BNK2 in a plan view. The metal layer MT may include a structure retracted (or recessed) with respect to the second bank BNK2 at the top surface of the first bank BNK1. Accordingly, a top surface of the metal layer MT may not be exposed.

A risk that the metal layer MT will be damaged during a manufacturing process of the display device DD may be reduced. For example, in case that the light controlling layer LCL is manufactured, the lower capping layer CPL_Q for passivating some components of the light controlling layer LCL may be formed. Due to a voltage environment formed to deposit (e.g., Chemical Vapor Deposition (CVD)) the lower capping layer CPL_Q, an arcing phenomenon on the metal layer MT may occur, and a lift-off risk of the metal layer MT may occur. However, in accordance of the embodiment of the disclosure, the top surface of the metal layer MT may not be exposed by the second bank BNK2, the arcing phenomenon can be reduced, and the lift-off risk of the metal layer MT can be reduced.

The second bank BNK2 may be disposed on the metal layer ML. The second bank BNK2 may be adjacent to the first bank BNK1 with the metal layer MT disposed therebetween. The second bank BNK2 may be passivated by the lower capping layer CPL_Q.

The second bank BNK2 may be disposed in a partial area on the display layer DL. The second bank BNK2 may be patterned, may expose a portion of the display layer DL, and may expose a portion of the top surface of the first bank BNK1.

The second bank BNK2 may surround an area and form spaces in which the light controlling structures LCS can be disposed.

In some embodiments, the second bank BNK2 may not overlap the sub-pixel areas SPXA in a plan view. For example, the second bank BNK2 may be disposed between the sub-pixel areas SPXA in a plan view.

The second bank BNK2 may entirely cover the top surface of the metal layer ML. In some embodiments, the second bank BNK2 may expose the side surface of the metal layer ML. A bottom surface of the second bank BNK2 may be exposed in an area adjacent to the metal layer MT. The second bank BNK2 may include a tip structure protruding with respect to the top surface of the metal layer ML. Accordingly, as described above, a structure in which the top surface of the metal layer may be entirely covered may be formed.

The second bank BNK2 may expose the top surface of the first bank BNK1. For example, the second bank BNK2 may expose the top surface of the first bank BNK1 which may be exposed by the metal layer MT.

The second bank BNK2 may include a light transmissive material (e.g., a transparent material). The second bank BNK2 may not include a light blocking material. For example, the second bank BNK2 may include an organic material. In some embodiments, the second bank BNK2 may include an acrylic material. However, the disclosure is not limited thereto.

In some embodiments, as the second bank BNK2 adjacent to the light controlling structure LCS may include the light transmissive material instead of the light blocking material, the light loss risk of light provided by the light emitting element LD can be reduced, and accordingly the light emission efficiency can be improved.

The second bank BNK2 may be formed with a spacer CS through a same process, and the second bank BNK2 and the spacer CS may include a same material. Accordingly, process steps can be simplified, and process cost can be reduced.

The light controlling structure LCS may be disposed in an area surrounded by the first bank BNK1. The light controlling structure LCS may be disposed in an area surrounded by the second bank BNK2. The light controlling structure LCS may be disposed in an area facing the metal layer MT. The light controlling structure LCS may not overlap the spacer CS in a plan view.

In some embodiments, the light controlling structure LCS may be directly adjacent to (e.g., in contact with) the metal layer MT. In some embodiments, a portion of the light controlling structure LCS may be adjacent to the metal layer MT between the second bank BNK2 and the encapsulation layer TFE. The light controlling structure LCS may be passivated by the lower capping layer CPL_Q.

The light control structure LCS may include a first color conversion layer CCL1, a second color conversion layer CCL2, and a light scattering layer SCL. The first color conversion layer CCL1, the second color conversion layer CCL2, and the light scattering layer SCL may be spaced apart from each other in a plan view in which the base layer BSL may be disposed.

The light controlling structure LCS may overlap each sub-pixel area SPXA in a plan view. For example, the first color conversion layer CCLI may overlap a first sub-pixel area SPXAl in a plan view. The second color conversion layer CCL2 may overlap a second sub-pixel area SPXA2 in a plan view. The light scattering layer SCL may overlap a third sub-pixel area SPXA3 in a plan view.

The first color conversion layer CCL1 may include a first color conversion particle for converting light (e.g., light of the third color) provided from the light emitting element LD into light of a first color. For example, the first color conversion layer CCL1 may include a first quantum dot for converting light of the third color into light of the first color. The first quantum dot may absorb light of the third color and emit light of the first color by shifting the wavelength of the light of the third color according to energy transition. The first quantum dot may be dispersed and provided in a matrix layer such as an organic material.

The second color conversion layer CCL2 may include a second color conversion particle for converting light (e.g., light of the third color) provided from the light emitting element LD into light of the second color. For example, the second color conversion layer CCL2 may include a second quantum dot for converting light of the third color into light of the second color. The second quantum dot may absorb light of the third color and emit light of the second color by shifting the wavelength of the light of the third color according to energy transition. The second quantum dot may be dispersed and provided in a matrix layer such as an organic material.

The light scattering layer SCL may be configured to scatter applied light. The light scattering layer SCL may improve light emission efficiency (e.g., a luminance), and improve a viewing angle characteristic of the display device DD. The light scattering layer SCL may include a scatterer. The scatterer may be dispersed and provided in a matrix layer such as an organic material. The scatterer may include a light scattering particle. For example, the scatterer may include at least one selected from the group consisting of silica (SiOₓ) (e.g., silica bead, hollow silica, or the like), titanium oxide (TiOₓ), zirconium oxide (ZrOₓ), aluminum oxide (AlₓO_{y}), indium oxide (InₓO_{y}), zinc oxide (ZnOₓ), tin oxide (SnOₓ), and antimony oxide (SbₓO_{y}). However, the disclosure is not limited thereto.

The spacer CS may be disposed on the first bank BNK1. The spacer CS may be disposed on the metal layer MT disposed on the first bank BNK1. The spacer CS may not overlap the sub-pixel area SPXA in a plan view. The spacer CS may be passivated by the lower capping layer CPL_Q.

The spacer CS may be disposed upwardly of the first color conversion layer CCL1, the second color conversion layer CCL2, and the light scattering layer SCL with respect to a base (e.g., an uppermost layer of the display layer DL) on which the light controlling layer LCL may be disposed. For example, the spacer CS may protrude in a thickness direction of the base layer BSL (e.g., the third direction DR3).

The spacer CS may form a separation distance between other components of the light controlling layer LCL and a color filter layer CFL. A filling layer FIL may be disposed between the color filter layer CFL and the light controlling layer LCL, thereby preventing damage of each layer of the display device DD in case that the display device DD is manufactured.

The spacer CS may be manufactured through a same process as the second bank BNK2. The spacer CS and the second bank BNK2 may include a same material. For example, the spacer CS and the second bank BNK2 may be manufactured through a same photolithography process. Accordingly, process steps for forming the spacer CS may be simplified so that process cost can be reduced.

The lower capping layer CPL_Q may be disposed on the light controlling structure LCS, a portion of the top surface of the first bank BNK1, the second bank BNK2, a side surface of the metal layer MT, and the spacer CS to passivate each component.

The lower capping layer CPL_Q may be an inorganic layer and may include at least one selected from the group consisting of silicon nitride (SiNₓ), aluminum nitride (AlNₓ), titanium nitride (TiNₓ), silicon oxide (SiOₓ), aluminum oxide (AlₓO_{y}), titanium oxide (TiOₓ), silicon oxycarbide (SiOₓC_{y}), and silicon oxynitride (SiOₓN_{y}). However, the disclosure is not limited thereto.

In some embodiments, the lower capping layer CPL_Q may be in contact with a portion of the top surface of the first bank BNK1 which may be exposed by the metal layer MT. At least a portion of the lower capping layer CPL_Q may be adjacent (e.g., directly adjacent) to the side surface of the metal layer MT which may be exposed by the second bank BNK2.

The filling layer FIL may be disposed between the light controlling layer LCL and the color filter layer CFL. The filling layer FIL may be disposed between an upper capping layer CPL_U and the lower capping layer CPL_Q. The filling layer FIL may include various transparent organic materials, but examples of the transparent organic materials are not particularly limited.

The color filter layer CFL may include the upper capping layer CPL_U, an optical layer LRL, color filters CF, and an upper layer UPL.

The upper capping layer CPL_U may be disposed between the optical layer LRL and the filling layer FIL. The upper capping layer CPL_U may be disposed throughout the sub-pixel areas SPXA and a non-sub-pixel area as an area except (or external to) the sub-pixel areas SPXA. The upper capping layer CPL_U may passivate the optical layer LRL. The upper capping layer CPL_U may include at least one of the examples described above with reference to the lower capping layer CPL_Q.

The optical layer LRL may be disposed between the color filter layer CFL and the upper capping layer CPL_U. The optical layer LRL may be disposed throughout the sub-pixel areas SPXA and the non-sub-pixel area as the area except the sub-pixel areas SPXA.

The optical layer LRL may have a refractive index greater than a refractive index of each of layers forming the color filters CF. The optical layer LRL may have a refractive index smaller than a refractive index of each of the first and second color conversion layers CCL1 and CCL2 and form a light recycling structure.

The optical layer LRL may include various materials to have a refractive index. For example, the optical layer LRL may include various resins and hollow silica. In another example, the optical layers LRL may include zirconium oxide (ZrOₓ). However, the disclosure is not limited thereto.

In some embodiments, the optical layer LRL may be designated as a low refractive layer.

The color filter layer CFL may be disposed on the bottom of the upper layer UPL. The color filter layer CFL may be disposed between the upper layer UPL and the optical layer LRL.

The color filter layer CFL may include the color filters CF, the color filters CF may include a first color filter CF1, a second color filter CF2, and a third color filter CF3.

The first color filter CF1 may be disposed in the first sub-pixel area SPXA1. The first color filter CF1 may include a color filter material (e.g., a dye or a pigment) allowing light of the first color (e.g., red) to be selectively transmitted therethrough.

The second color filter CF2 may be disposed in the second sub-pixel area SPXA2. The second color filter CF2 may include a color filter material (e.g., a dye or a pigment) allowing light of the second color (e.g., green) to be selectively transmitted therethrough.

The third color filter CF3 may be disposed in the third sub-pixel area SPXA3. The third color filter CF3 may include a color filter material (e.g., a dye or a pigment) allowing light of the third color (e.g., blue) to be selectively transmitted therethrough.

In some embodiments, the non-sub-pixel area in which light of a color may not be viewed may be formed between the sub-pixel areas SPXA. In some embodiments, the first color filter CF1, the second color filter CF2, and the third color filter CF3 may overlap each other in the non-sub-pixel area in a plan view, and a light blocking structure LBS may be formed in the non-sub-pixel area.

In the first sub-pixel area SPXA1, light emitted from the light emitting element LD may be provided as light of the first color while being transmitted through the first color conversion layer CCL1. The light transmitted through the first color conversion layer CCL1 may be provided as light of the first color while being transmitted through the first color filter CF1. Accordingly, the first sub-pixel SPX1 may be configured to provide the light of the first color.

In the second sub-pixel area SPXA2, light emitted from the light emitting element LD may be provided as light of the second color while being transmitted through the second color conversion layer CCL2. The light transmitted through the second color conversion layer CCL2 may be provided as light of the second color. Accordingly, the second sub-pixel SPX2 may be configured to provide the light of the second color.

In the third sub-pixel area SPXA3, light emitted from the light emitting element LD may be provided as light of a same color as the emitted light. The light transmitted through the light scattering layer SCL may be provided as light of the third color while being transmitted through the third color filter CF3. Accordingly, the third sub-pixel SPX3 may be configured to provide the light of the third color.

The upper layer UPL may be disposed on the color filter layer CFL. In some embodiments, the upper layer UPL may be a base member for disposing other layers forming the color filter layer CFL. For example, the upper layer UPL may be an upper substrate. In some embodiments, the upper layer UPL may include a glass substrate. However, the disclosure is not limited thereto.

Next, a display device DD according to an embodiment of the disclosure will be described with reference to FIG. 6. In FIG. 6, portions overlapping those described above with reference to FIG. 5 will be briefly described or will not be repeated.

Referring to FIG. 6, the display device DD′ according to an embodiment of the disclosure may be different from the display device DD according to the above-described embodiment in that the first bank BNK1′ overlaps the third sub-pixel area SPXA3 in a plan view.

At least a portion of the first bank BNK1′ may be disposed in the third sub-pixel area SPXA3. At least a portion of the top surface of the first bank BNK1′ may be exposed by the metal layer MT and the second bank BNK2 and overlap the third sub-pixel area SPXA3.

The first bank BNK1′ may be a light transmissive bank structure including a scatterer. For example, the first bank BNK1′ may include the scatterer including a light scattering particle. The scatterer may include at least one selected from the group consisting of silica (SiOₓ) (e.g., silica bead, hollow silica, or the like), titanium oxide (TiOₓ), zirconium oxide (ZrOₓ), aluminum oxide (AlₓO_{y}), indium oxide (InₓO_{y}), zinc oxide (ZnOₓ), tin oxide (SnOₓ), and antimony oxide (SbₓO_{y}). However, the disclosure is not limited thereto.

In some embodiments, the first bank BNK1′ may be disposed in the third sub-pixel area SPXA3 and scatter light provided from the light emitting element LD. Accordingly, the formation of the light scattering layer SCL described above with reference to FIG. 5 may be omitted and process steps can be simplified.

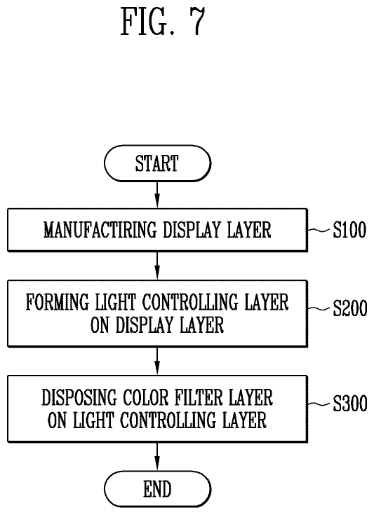

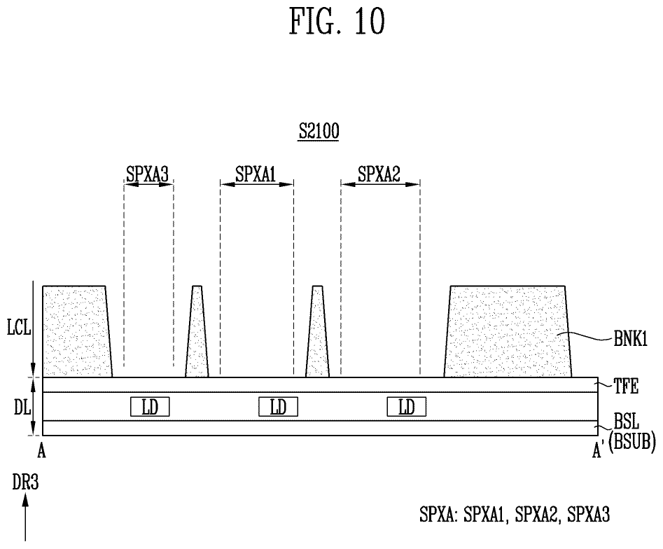

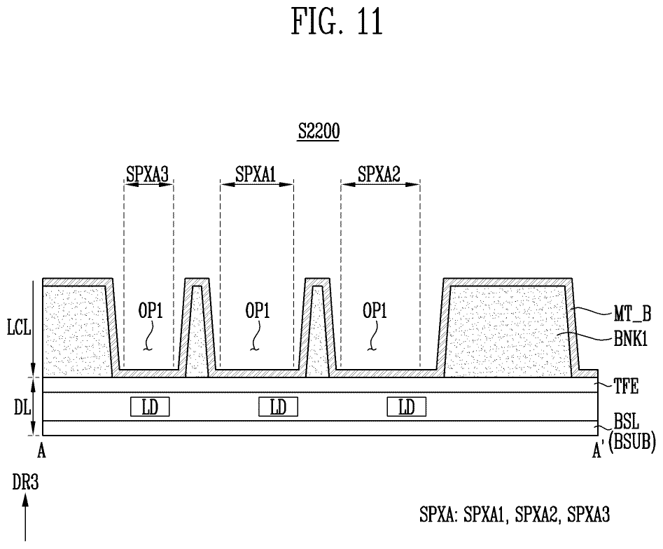

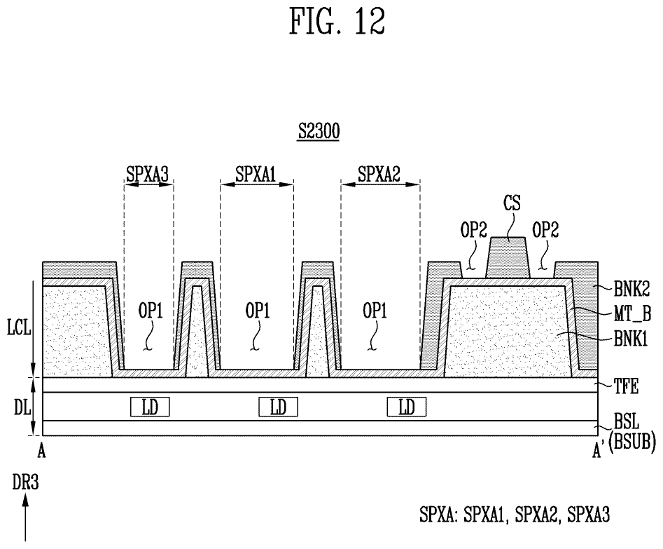

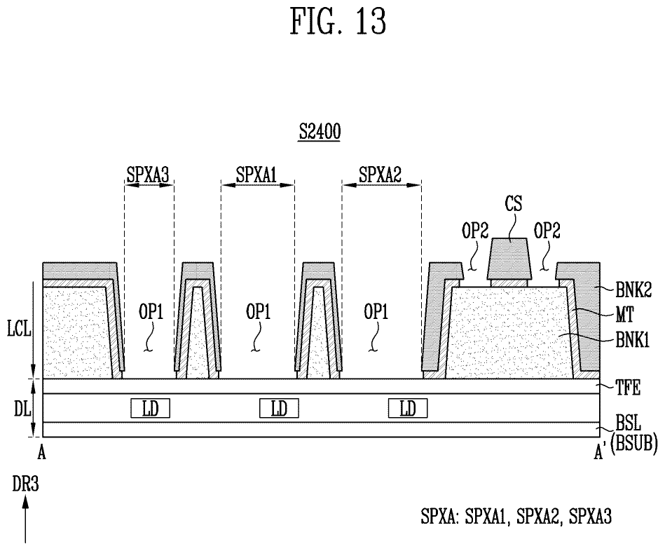

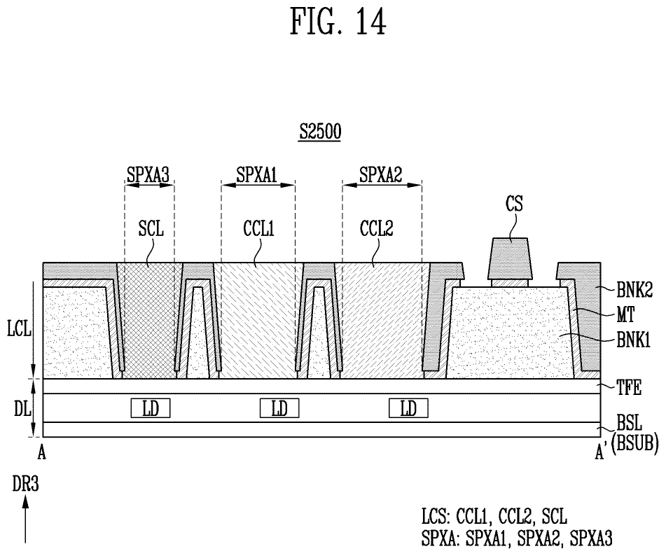

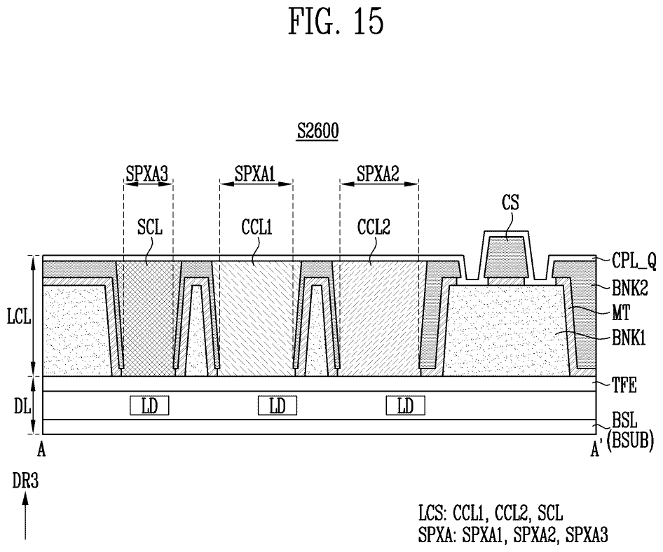

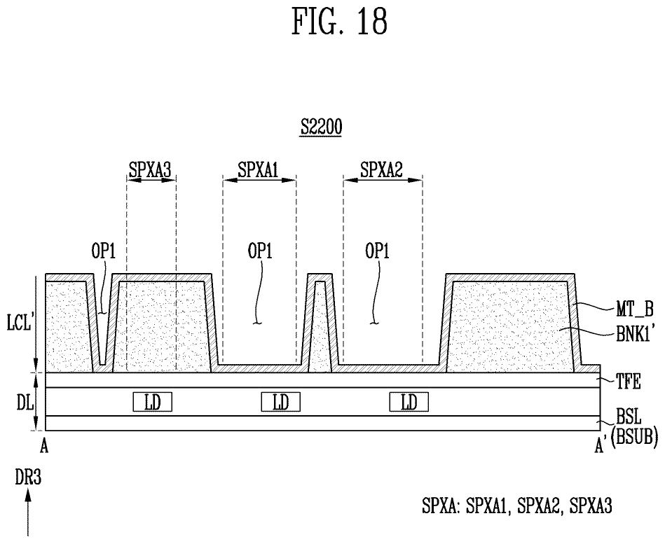

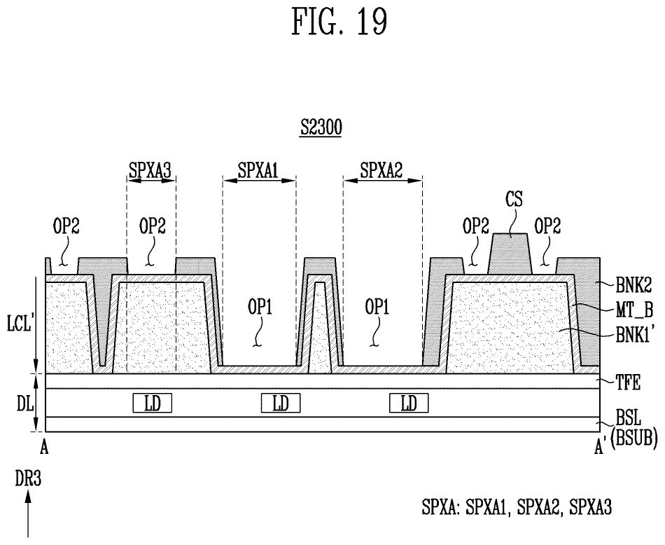

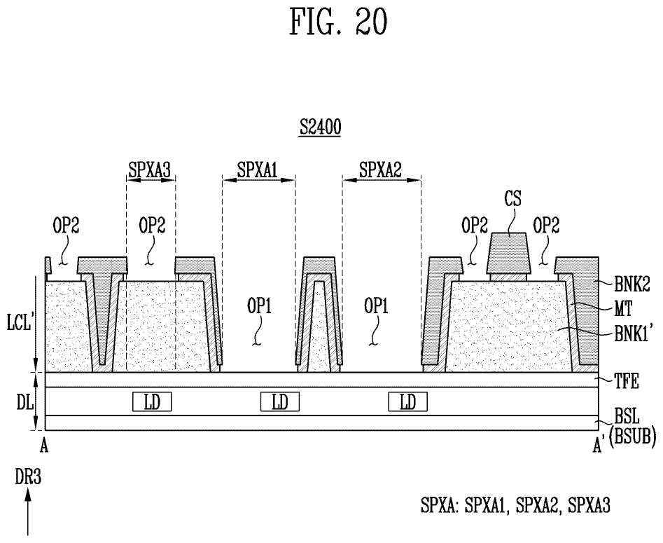

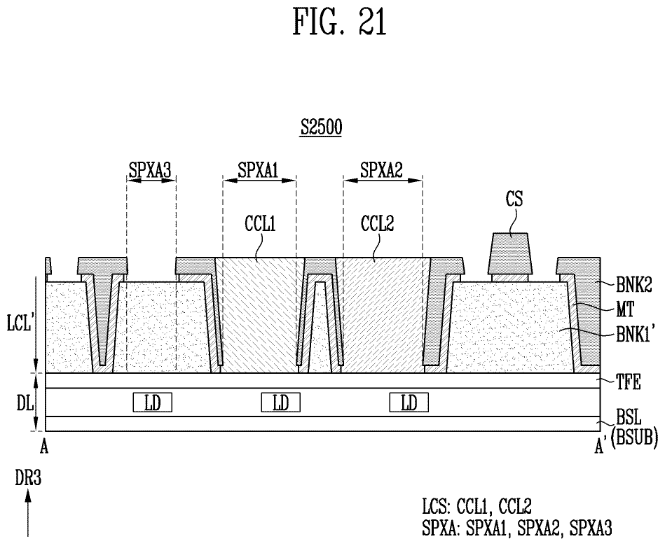

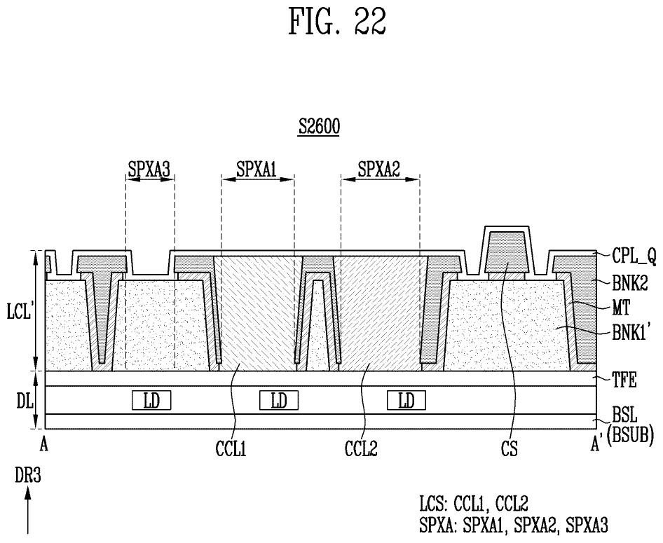

Next, a method of manufacturing display devices DD and DD′ according to an embodiment of the disclosure will be described with reference to FIGS. 7 to 23. In FIGS. 7 to 23, portions overlapping with those described above will be briefly described or will not be repeated.

The display devices DD and DD′ according to the embodiment of the disclosure may be manufactured by forming a display layer DL and a light controlling layer LCL or LCL' on a base layer BSL or lower substrate BSUB, forming a color filter layer CFL on an upper layer UPL or upper substrate, and bonding the two formed structures to each other. However, the disclosure is not necessarily limited thereto. In some embodiments, the display devices DD and DD′ according to the embodiment of the disclosure may be manufactured by forming the light controlling layer LCL or LCL' on the upper layer UPL.

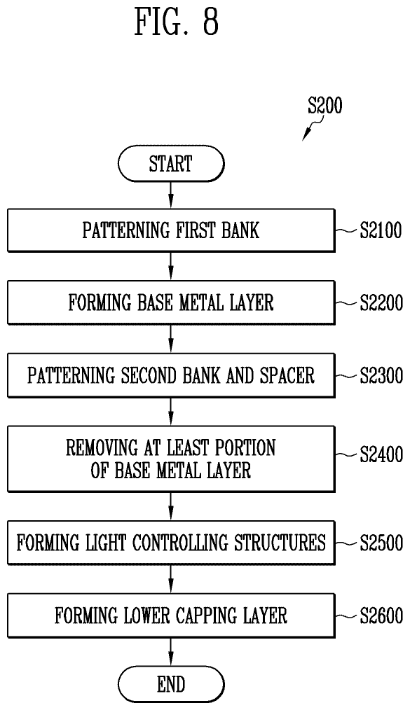

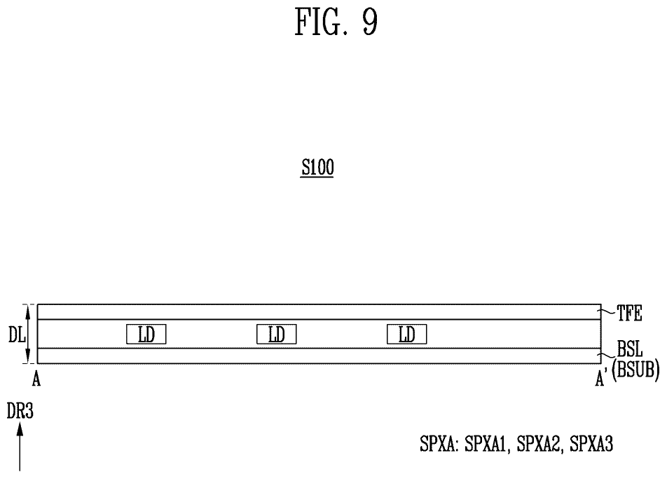

FIG. 7 is a flowchart illustrating a method of manufacturing a display device according to an embodiment of the disclosure. FIG. 8 is a flowchart illustrating detailed steps of a step of forming a light controlling layer on a display layer according to an embodiment of the disclosure. FIGS. 9 to 23 are schematic sectional views illustrating process steps of the method of manufacturing the display devices according to an embodiment of the disclosure.

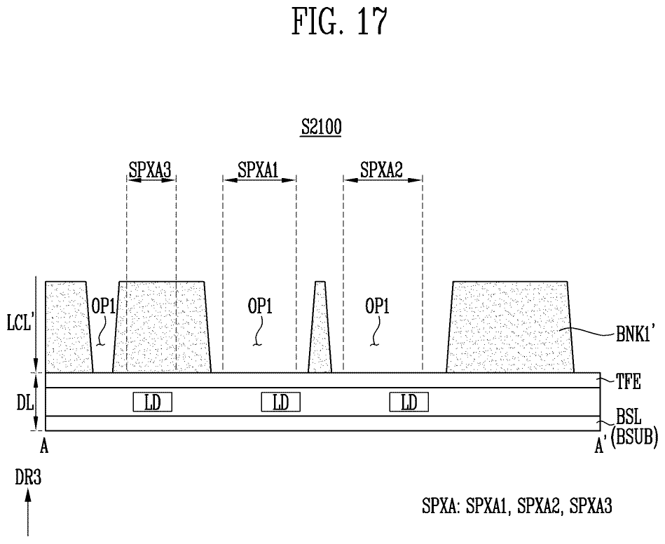

FIGS. 9 to 16 schematically illustrate a method of manufacturing the display device DD according to the embodiment described above with reference to FIG. 5. FIGS. 17 to 23 schematically illustrate a method of manufacturing the display device DD′ according to an embodiment described above with reference to FIG. 6.

First, the method of manufacturing the display device DD according to the embodiment of the disclosure will be described with reference to FIGS. 7 to 16.

Referring to FIG. 7, the method of manufacturing the display device DD according to the embodiment of the disclosure may include step S100 of manufacturing a display layer, step S200 of forming a light controlling layer on the display layer, and step S300 of disposing a color filter layer on the light controlling layer.

Referring to FIG. 8, the step S200 of forming the light controlling layer on the display layer may include step S2100 of patterning a first bank, step S2200 of forming a base metal layer, step S2300 of patterning a second bank and a spacer, step S2400 of removing at least a portion of the base metal layer, step S2500 of forming light controlling structures, and step S2600 of forming a lower capping layer.

Referring to FIGS. 7 and 9, in the step S100 of manufacturing the display layer, layers forming a display layer DL may be disposed on a lower substrate BSUB (e.g., a base layer BSL).

In some embodiments, a conductive layer or an insulating layer on the lower substrate BSUB (or an upper layer UPL) may be formed based on an ordinary process for manufacturing a semiconductor device. For example, a conductive layer or an insulating layer on the base layer BSL may be formed through a photolithography process, be etched through various processes (wet etching, dry etching, and the like), and be deposited through various processes (sputtering, chemical vapor deposition, and the like). However, the disclosure is not necessarily limited to a specific example.

In this step S100, a pixel circuit PXC may be patterned on the base layer BSL thereby forming a pixel circuit layer PCL, and light emitting elements LD may be disposed on the pixel circuit layer PCL. In some embodiments and in this step S100, the light emitting elements LD may be disposed on the base layer BSL (e.g., the pixel circuit layer PCL) through various processes. In some embodiments, an encapsulation layer TFE may be formed at a roughly uppermost portion of the display layer DL.

In this step S100 and in conjunction with FIG. 4, the light emitting element LD may include an organic light emitting diode. The light emitting element LD may be manufactured on the base layer BSL through a deposition process.

Referring to FIGS. 7, 8, and 10, in the step S200 of forming the light controlling layer on the display layer, the step S2100 of patterning the first bank may be performed.

In this step S2100, a first bank BNK1 may be disposed on the display layer DL (e.g., the encapsulation layer TFE). The first bank BNK1 may be patterned through a photolithography process. For example, in order to form the first bank BNK1, a light transmissive material (e.g., a transparent material) may be deposited, and a layer including the deposited light transmissive material may be etched thereby manufacturing the first bank BNK1.

In this step S2100, the first bank BNK1 may be disposed in a partial area on the pixel circuit layer PCL, and areas for sub-pixel areas SPXA may be approximately defined as subsequent processes may be performed. For example, in this step S2100, a first opening OP1 surrounded by the first bank BNK1 may be formed. The first opening OP1 may overlap each of the sub-pixel areas SPXA in a plan view. For convenience of description, positions of first to third sub-pixel areas SPXA1 to SPXA3 are schematically illustrated in subsequent drawings.

Referring to FIGS. 7, 8, and 11, in the step S200 of forming the light controlling layer on the display layer, the step S2200 of forming the base metal layer may be performed.

In this step S2200, a base metal layer MT_B may be formed (e.g., deposited). Accordingly, the base metal layer MT_B may be entirely disposed in the sub-pixel areas SPXA and areas adjacent thereto. The base metal layer MT_B may cover the first bank BNK1 the encapsulation layer TFE.

In this step S2200, at least a portion of the base metal layer MT_B may be disposed in the first opening OP1. The base metal layer MT_B may cover (e.g., entirely cover) a top surface of the first bank BNK1. In some embodiments, the base metal layer MT_B may include a reflective metal.

Referring to FIGS. 7, 8, and 12, in the step S200 of forming the light controlling layer on the display layer, the step S2300 of patterning the second bank and the spacer may be performed.

In this step S2300, a second bank BNK2 may be patterned in an area not overlapping with the sub-pixel areas SPXA. The second bank BNK2 may be patterned through a photolithography process. A spacer CS may be formed through a same photolithography process as the second bank BNK2. For example, in order to form the second bank BNK2 and the spacer CS, a light transmissive material (e.g., a transparent material) may be deposited, and a layer including the deposited light transmissive material may be etched, thereby manufacturing the second bank BNK2 and the spacer CS.

In this step S2300, the second bank BNK2 may be patterned to surround the first opening OP1, and a second opening OP2 may be formed which exposes at least a portion of the base metal layer MT_B.

The spacer CS manufactured in this step S2300 may protrude with respect to the base layer BSL as compared with the second bank BNK2, and be adjacent (e.g., directly adjacent) to the second opening OP2. For example, the spacer CS may be entirely surrounded by the second opening OP2.

Referring to FIGS. 7, 8, and 13, in the step S200 of forming the light controlling layer on the display layer, the step S2400 of removing at least a portion of the base metal layer may be performed.

In this step S2400, at least a portion of the base metal layer MT_B may be etched, and a metal layer MT may be provided which does not overlap the sub-pixel area SPXA. In this step S2400, the metal layer MT may form a reflective surface facing the sub-pixel area SPXA.

In this step S2400, a portion of the base metal layer MT_B, which overlaps the first opening OP1 in a plan view may be removed. In some embodiments, the encapsulation layer TFE overlapping with the first opening OP1 in a plan view may be exposed.

In this step S2400, a portion of the base metal layer MT_B, which overlaps the second opening OP2 in a plan view may be removed. In some embodiments, the first bank BNK1 overlapping with the second opening OP2 in a plan view may be exposed.

In this step S2400, the metal layer MT may maintain a state in which the metal layer MT may not be exposed in a plan view. For example, at least a portion of the base metal layer MT_B, which may be covered by the second bank BNK2 or the spacer CS in a plan view, may be removed, and the metal layer MT may be entirely covered by the second bank BNK2 or the spacer CS.

Referring to FIGS. 7, 8, and 14, in the step S200 of forming the light controlling layer on the display layer, the step S2500 of forming the light controlling structures may be performed.

In this step S2500, a first color conversion layer CCL1, a second color conversion layer CCL2, and a light scattering layer SCL may be formed. For example, the first color conversion layer CCL1, the second color conversion layer CCL2, and the light scattering layer SCL may be disposed in corresponding sub-pixel areas SPXA, respectively. The first color conversion layer CCL1, the second color conversion layer CCL2, and the light scattering layer SCL may be formed through an inkjet process or a photolithography process. However, the disclosure is not limited thereto.

Referring to FIGS. 7, 8, and 15, in the step S200 of forming the light controlling layer on the display layer, the step S2600 of forming a lower capping layer may be performed.

In this step S2600, a lower capping layer CPL_Q may be deposited (e.g., chemical vapor deposited (CVD)). The lower capping layer CPL_Q may passivate layers of a light controlling layer LCL which are formed in previous steps. For example, the lower capping layer CPL_Q may passivate a light controlling structure LCS, the second bank BNK2, and the spacer CS. In some embodiments, the lower capping layer CPL_Q may be in contact with the first bank BNK1.

In some embodiments, the metal layer MT may be entirely covered by the second bank BNK2 in a plan view. Accordingly and as described above, in case that a deposition process for forming the lower capping layer CPL_Q is performed in this step S2600, an arcing phenomenon and a lift-off risk of the metal layer MT can be reduced.

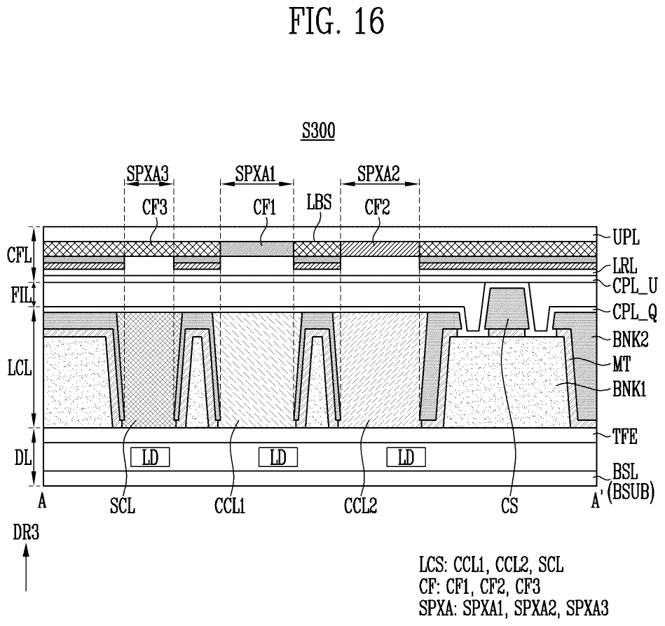

Referring to FIGS. 7 and 16, the step S300 of disposing the color filter layer on the light controlling layer may be performed.

In this step S300, color filters CF, an optical layer LRL, and an upper capping layer CPL_U may be sequentially disposed on the upper layer UPL forming an upper substrate, and accordingly a color filter layer CFL may be provided. A filling layer FIL may be disposed between the color filter layer CFL and the light controlling layer LCL so that the color filter layer CFL and the light controlling layer LCL may be bonded to each other. In this step S300, the spacer CS may be adjacent (e.g., directly adjacent) to the upper capping layer CPL_U.

In this step S300, the color filters CF may be patterned on the upper layer UPL through a photolithography process. Accordingly, first to third color filters CF1 to CF3 may be patterned to overlap the first to third sub-pixel areas SPXA1 to SPXA3, respectively, and a light blocking structure LBS may be formed in an area. The optical layer LRL may be formed on the color filters CF, and other layers of the color filter layer CFL may be passivated as the upper capping layer CPL_U may be formed on the optical layer LRL.

The method of manufacturing the display device DD′ according to an embodiment of the disclosure will be described with reference to FIGS. 7, 8, and 17 to 23.

Like the above-described method of manufacturing the display device, the method of manufacturing the display device DD' according to an embodiment of the disclosure may include step S100 of manufacturing a display layer, step S200 of forming a light controlling layer on the display layer, and step S300 of disposing a color filter layer on the light controlling layer. The step S200 of forming the light controlling layer on the display layer may include step S2100 of patterning a first bank, step S2200 of forming a base metal layer, step S2300 of patterning a second bank and a spacer, step S2400 of removing at least a portion of the base metal layer, step S2500 of forming light controlling structures, and step S2600 of forming a lower capping layer. However, portions overlapping with those described above will be briefly described or will not be repeated.

Referring to FIGS. 7, 8, and 17, in the step S2100 of patterning the first bank, at least a portion of a first bank BNK1′ may be formed in an area for forming the third sub-pixel area SPXA3.

In some embodiments, after a layer including a scatterer may be formed to pattern the first bank BNK1′, the formed layer may be patterned. The first bank BNK1′ may not be disposed in areas in which the first and second sub-pixel areas SPXA1 and SPXA2 may be to be formed.

Referring to FIGS. 7, 8, and 18, in the step S2200 of forming the base metal layer, a base metal layer MT_B covering a portion of the first bank BNK1 in the third sub-pixel area SPXA3 may be formed.

Referring to FIGS. 7, 8, and 19, in the step S2300 of patterning the second bank, at least a portion of the metal layer MT_B in the third sub-pixel area SPXA3 may be exposed, thereby patterning a second bank BNK2 forming a second opening OP2.

In this step S2300, at least a portion of the second bank BNK2 may be disposed to be adjacent (e.g., directly adjacent) to the third sub-pixel area SPXA3 in a plan view, and may not be disposed in the third sub-pixel area SPXA3.

Referring to FIGS. 7, 8, and 20, in the step S2400 of removing at least a portion of the base metal layer, at least a portion of the base metal layer MT_B in the third sub-pixel area SPXA3 may be removed, and a metal layer MT may be provided.

In this step S2400, at least a portion of a top surface of the first bank BNK1′ in the third sub-pixel area SPXA3 may be exposed.

Referring to FIGS. 7, 8, and 21, in the step S2500 of forming the light controlling structures, first and second color conversion layers CCL1 and CCL2 may be formed.

In this step S2500, any additional light scattering structure (e.g., the light scattering layer SCL) may not be formed in the third sub-pixel area SPXA3. Accordingly, process steps can be simplified, and process cost can be reduced.

Referring to FIGS. 7, 8, and 22, in the step S2600 of forming the lower capping layer, a lower capping layer CPL_Q may passivate other layers of a light controlling layer LCL′.

In this step S2600, the lower capping layer CPL_Q may be in contact with the first bank BNK1′ in the third sub-pixel area SPXA3.

According to the embodiment of the disclosure, as described above, the metal layer MT can be entirely covered by the second bank BNK2 in a plan view, and thus an arcing phenomenon and a lift-off risk of the metal layer MT can be reduced in case that the lower capping layer CPL_Q is formed.

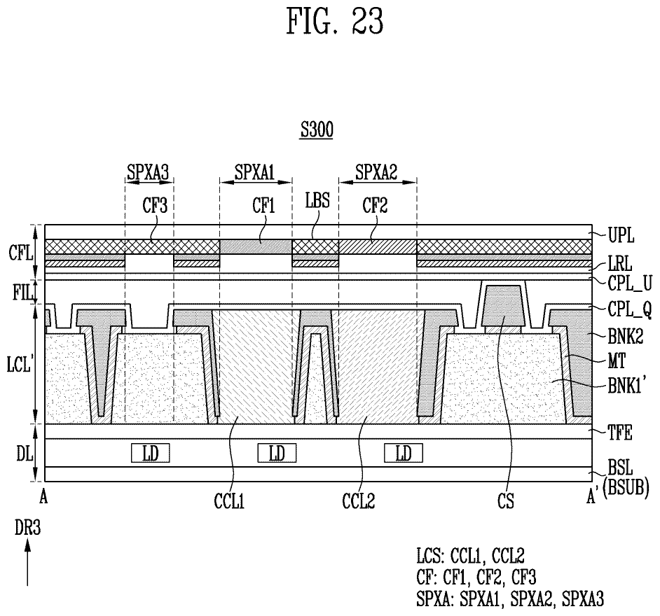

Referring to FIGS. 7 and 23, in the step S300 of disposing the color filter layer on the light controlling layer, a filling layer FIL may be disposed between the light controlling layer LCL′ and a color filter layer CFL. Accordingly, the display device including a structure in which the color filter layer CFL may be disposed on the light controlling layer LCL′ may be provided.

According to the disclosure, there can be provided a display device and a method of manufacturing a display device in which light emission efficiency can be improved.

According to the disclosure, there can be provided a display device and a method of manufacturing a display device in which process efficiency can be improved.

According to the disclosure, there can be provided a display device and a method of manufacturing a display device in which damage of layers forming the display device can be prevented.

Example embodiments have been disclosed herein, and although specific terms may be employed, they may be used and may be interpreted in a generic and descriptive sense only and not for purpose of limitation. In some instances, as would be apparent to one of ordinary skill in the art as of the filing of the application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the disclosure as set forth in the following claims.

What is claimed is:

1. A display device comprising:
a display layer; and
a light controlling layer disposed on the display layer, the light controlling layer including:
a first bank;
a metal layer, at least a portion of the metal layer being disposed on the first bank, and the metal layer exposing a top surface of the first bank; and
a second bank, at least a portion of the second bank being disposed on the metal layer, and the second bank exposing the top surface of the first bank.

2. The display device of claim 1, wherein
the light controlling layer includes a light controlling structure,
at least a portion of the light controlling structure is disposed in an area surrounded by the first bank, and
the light controlling structure includes:
a color conversion layer including a quantum dot; and
a light scattering layer including a scatterer.

3. The display device of claim 2, further comprising:
a first sub-pixel area to which light of a first color is provided;
a second sub-pixel area to which light of a second color is provided; and
a third sub-pixel area to which light of a third color is provided, wherein the color conversion layer includes:
a first color conversion layer disposed in the first sub-pixel area; and
a second color conversion layer disposed in the second sub-pixel area, and the light scattering layer is disposed in the third sub-pixel area.

4. The display device of claim 3, further comprising:
a color filter layer including:
a first color filter overlapping the first sub-pixel area,
a second color filter overlapping the second sub-pixel area, and
a third color filter overlapping the third sub-pixel area,
wherein the display layer includes a light emitting element providing light including a light component of the third color.

5. The display device of claim 1, wherein
each of the first bank and the second bank includes a light transmissive material, and
the metal layer includes a reflective material.

6. The display device of claim 1, wherein the metal layer is entirely covered by the second bank in a plan view.

7. The display device of claim 1, wherein a side surface of the metal layer is exposed by the second bank.

8. The display device of claim 1, wherein the metal layer includes a structure retracted with respect to the second bank.

9. The display device of claim 1, further comprising:
a spacer disposed on the top surface of the first bank,
wherein the spacer and the second bank include a same material.

10. The display device of claim 2, further comprising:
a lower capping layer passivating the second bank and the light controlling structure,
wherein the lower capping layer is in contact with a portion of the top surface of the first bank that is exposed by the metal layer.

11. The display device of claim 1, wherein the first bank and the second bank are physically spaced apart from each other.

12. The display device of claim 1, further comprising:
a first sub-pixel area to which light of a first color is provided;
a second sub-pixel area to which light of a second color is provided; and
a third sub-pixel area to which light of a third color is provided,
wherein the first bank does not overlap the first sub-pixel area and the second sub-pixel area in a plan view, and
the first bank overlaps the third sub-pixel area in a plan view.

13. The display device of claim 12, wherein
the first color is red,
the second color is green, and
the third color is blue.

14. The display device of claim 12, wherein the first bank includes a scatterer.

15. A method of manufacturing a display device, the method comprising:
manufacturing a display layer; and
forming a light controlling layer on the display layer,
wherein the forming of the light controlling layer includes:
patterning a first bank;
forming a base metal layer covering the first bank;
patterning a second bank and a spacer which cover the base metal layer;
removing at least a portion of the base metal layer which is exposed by the second bank; and
forming a light controlling structure in an area surrounded by the first bank.

16. The method of claim 15, wherein
a metal layer including a reflective surface is formed by the removing of the at least the portion of the base metal layer,
each of the first bank and the second bank includes a light transmissive material, and
the metal layer includes a reflective material.

17. The method of claim 16, further comprising:
forming a lower capping layer passivating the second bank and the light controlling structure,
wherein in the forming of the lower capping layer, the metal layer is entirely covered by the second bank in a plan view.

18. The method of claim 15, wherein
the display device includes:
a first sub-pixel area to which light of a first color is provided;
a second sub-pixel area to which light of a second color is provided; and
a third sub-pixel area to which light of a third color is provided, and the forming of the light controlling structure includes:
forming a first color conversion layer including a first quantum dot in the first sub-pixel area;
forming a second color conversion layer including a second quantum dot in the second sub-pixel area; and
forming a light scattering layer including a scatterer in the third sub-pixel area.

19. The method of claim 15, further comprising:
forming a lower capping layer passivating the second bank and the light controlling structure, wherein the display device includes:
a first sub-pixel area to which light of a first color is provided;
a second sub-pixel area to which light of a second color is provided; and
a third sub-pixel area to which light of a third color is provided,
the first bank includes a scatterer, and
the first bank overlaps the third sub-pixel area in a plan view.

20. The method of claim 19, wherein the lower capping layer and the first bank are in contact with each other in the third sub-pixel area.
